(19) United States
(12) Patent Application Publication
(10) Pub. No.: US 2006/0232167 A1
(43) Pub. Date: Oct. 19, 2006

(54) PIEZOELECTRIC DIAPHRAGM WITH APERTURE(S)

(75) Inventor: Tony JORDAN, Cumming, GA (US)

Correspondence Address: NIXON & VANDERHYE, PC, 901 NORTH GLEBE ROAD, 11TH FLOOR, ARLINGTON, VA, 22203, US

(73) Assignee: PAR Technologies LLC, Hampton, VA (US)

(21) Appl. No.: 11/279,645

(22) Filed: Apr. 13, 2006

Related U.S. Application Data
(60) Provisional application No. 60/670,650, filed on Apr. 13, 2005.

(51) Int. Cl. H01L 41/08

(52) U.S. Cl. 310/324

(57) ABSTRACT

A piezoelectric diaphragm member (23) has an aperture (25). Preferably the piezoelectric diaphragm (23) is a multi-layer composite which includes a piezoelectric wafer layer. In some embodiments, the aperture (25) in the piezoelectric diaphragm accommodates a diaphragm accessory or fixture. The diaphragm accessory or fixture is preferably inserted through the plural layers of the multi-layer composite piezoelectric diaphragm member, and as such has an accessory or fixture body suitably sized for snug (e.g., fluid-tight) insertion or adhesion into the diaphragm aperture. Within its periphery the accessory or fixture body can include a feature such as a valve (e.g., ball valve, duckbill, flapper valve) or a projection (e.g., a stud or standoff, for example). The projection of the fixture or accessory can be configured, arranged, or adapted to engage or actuate further apparatus. In other embodiments, the aperture (25) in the piezoelectric diaphragm (23) is selectively opened and closed by a closure member such as a valve flap (27) which acts in response to movement of the piezoelectric diaphragm (23).

### BACKGROUND

This application claims the priority and benefit of the following U.S. Provisional Patent Application, which is incorporated by reference herein in its entirety: U.S. Provisional Patent Application 60/670,650, filed Apr. 13, 2005, entitled VALVING PIEZOELECTRIC DIAPHRAGM FOR PUMP.

### FIELD OF THE INVENTION

The present invention pertains to piezoelectric diaphragms, to methods of fabricating or manufacturing piezoelectric diaphragms, and to pumps which incorporate or include piezoelectric diaphragms as actuators.

### RELATED ART AND OTHER CONSIDERATIONS

Examples of pumps with piezoelectric diaphragms are shown in PCT Patent Application PCT/US01/28947, filed 14 Sep. 2001; U.S. patent application Ser. No. 10/380,547, filed Mar. 17, 2003, entitled “Piezoelectric Actuator and Pump Using Same”; U.S. patent application Ser. No. 10/380,589, filed Mar. 17, 2003, entitled “Piezoelectric Actuator and Pump Using Same”, and U.S. Provisional Patent Application 60/670,657 filed Apr. 13, 2005, entitled “PIEZOELECTRIC DIAPHRAGM ASSEMBLIES AND METHODS OF MAKING SAME”, all of which are incorporated herein by reference.

When used in pump and similar apparatus, diaphragms typically define a fluid chamber and confine fluid to the chamber, so that fluid ingresses and egresses on a same side of the piezoelectric diaphragm. Other configurations of piezoelectric pumps are also desirable.

### BRIEF SUMMARY

A piezoelectric diaphragm member has an aperture. Preferably the piezoelectric diaphragm is a multi-layer composite which includes a piezoelectric wafer layer. In some embodiments, the aperture in the piezoelectric diaphragm accommodates a diaphragm accessory or fixture. The diaphragm accessory or fixture is preferably inserted through the plural layers of the multi-layer composite piezoelectric diaphragm member, and as such has an accessory or fixture body suitably sized for snug (e.g., fluid-tight) insertion or adhesion into the diaphragm aperture. Within its periphery the accessory or fixture body can include a feature such as a valve (e.g., ball valve, duckbill, flapper valve) or a projection (e.g., a stud or standoff, for example). The projection of the fixture or accessory can be configured, arranged, or adapted to engage or actuate further apparatus.

In other embodiments, the aperture in the piezoelectric diaphragm is selectively opened and closed by a closure member such as a valve flap which acts in response to movement of the piezoelectric diaphragm. The closure member may be on either side of the piezoelectric diaphragm member, with choice of location depending on upon particular environment of employment and fluid flow conditions therein.

In an example embodiment, the piezoelectric diaphragm member has an essentially circular shape, with the diaphragm aperture similarly being circularly shaped. The piezoelectric diaphragm member may be configured in other shapes, as may also be the diaphragm aperture and the corresponding diaphragm accessory or fixture which is inserted therein. The diaphragm aperture, diaphragm accessory or fixture, or closure member may be centrally positioned on the piezoelectric diaphragm member, or in any other suitable position. One or more diaphragm apertures, and hence one or more corresponding diaphragm accessories or fixtures, or closure members, may also be provided and arranged as desired.

As one aspect, a batch or lot of aperture-bearing piezoelectric diaphragm members can be produced with a specified or even standardized aperture, e.g., an aperture of a predetermined configuration and dimension(s). In view of such specified or standardized aperture, some of the diaphragm members of the lot can be fitted with diaphragm accessories or fixtures of a first type, while other members of the lot can be fitted with diaphragm accessories or fixtures of a second type, and so forth. By making the apertures of the piezoelectric diaphragm members of prearranged size and configuration, and by also making various types of diaphragm accessories or fixtures or closure members of suitable size and configuration for mating/insertion into the apertures, manufacturing capability is enhanced with interchangeable and easily configurable parts.

In an example embodiment, the diaphragm piezoelectric member is a multi-layer laminate comprising a piezoelectric core layer; a substrate; and a cover layer. In an example implementation, at least one of the substrate and the cover layer comprises stainless steel.

The piezoelectric diaphragm member has particularly advantageous use in a pump whose pump body has an inlet port and an opposed outlet port. The piezoelectric diaphragm member is positioned internally in the pump body. The piezoelectric diaphragm member at least partially defines an intake chamber substantially between the inlet port and the piezoelectric diaphragm. In addition, the piezoelectric diaphragm member at least partially defines an exhaust chamber substantially between the outlet port and the piezoelectric diaphragm. The piezoelectric diaphragm member has the diaphragm aperture provided therein. The piezoelectric diaphragm member carries the diaphragm accessory or closure member (e.g., valve flap) for selectively opening and closing the diaphragm aperture in response to movement of the piezoelectric diaphragm.

In an embodiment wherein the closure member is a flap valve, selective opening and closing of the diaphragm aperture by the flap valve selectively allows fluid communication between the intake chamber and the exhaust chamber. In such embodiment, the valve flap comprises a flexible material which responds to movement of the piezoelectric diaphragm member. In one such implementation, the valve flap at least partially uncovers the diaphragm aperture when the piezoelectric diaphragm member travels to a first position (e.g., a position either of essentially no, small, or minimum deflection), thereby permitting fluid communication between the intake chamber and the exhaust chamber. In such implementation, the valve flap essentially completely covers the diaphragm aperture when the piezoelectric diaphragm member travels to a second position (e.g., a position of larger deflection than the first position or even maximum deflection) so that the piezoelectric diaphragm member provides a continuous surface for driving fluid from the exhaust chamber.

### BRIEF DESCRIPTION OF THE DRAWINGS

The foregoing and other objects, features, and advantages of the invention will be apparent from the following more particular description of preferred embodiments as illustrated in the accompanying drawings in which reference characters refer to the same parts throughout the various views. The drawings are not necessarily to scale, emphasis instead being placed upon illustrating the principles of the invention.

FIG. 1A is an isometric view of a piezoelectric diaphragm member having an aperture.

FIG. 1B is an isometric view of a piezoelectric diaphragm member having a generic accessory or fixture inserted into a diaphragm aperture.

FIG. 2A and FIG. 2B are isometric views of a piezoelectric diaphragm member according to a first example embodiment.

FIG. 3 is a cross section side view of a pump which incorporates the piezoelectric diaphragm member of FIG. 2, with the piezoelectric diaphragm member being in a rest position and with no fluid in the pump.

FIG. 4 is a top view of the pump of FIG. 3.

FIG. 5A is a cross section side view of the pump of FIG. 3 showing the piezoelectric diaphragm member in a deflected position for priming the pump with fluid.

FIG. 5B is a cross section side view of the pump of FIG. 3 showing the piezoelectric diaphragm member in the course of returning from the deflected position to the rest position for permitting communication of fluid from an inlet chamber to an exhaust chamber.

FIG. 5C is a cross section side view of the pump of FIG. 3 showing the piezoelectric diaphragm member again in the rest position but with fluid in both the inlet chamber and the exhaust chamber.

FIG. 5D is a cross section side view of the pump of FIG. 3 showing the piezoelectric diaphragm member in the deflected position for expelling fluid from the exhaust chamber of the pump.

FIG. 6A-FIG. 6C are cross section side views of a pump according to another example embodiment.

FIG. 7 is a waveform diagram for a drive signal for a piezoelectric diaphragm member of the pump of FIG. 6A-FIG. 6B.

FIG. 8A-FIG. 8B, FIG. 9, FIG. 10, and FIG. 11 are sectioned side view of various embodiments of aperture accessories or fixtures insertable into a diaphragm aperture.

FIG. 12 is a perspective view of a piezoelectric diaphragm element having plural diaphragm apertures.

FIG. 13 is a diagrammatic view of an automated piezoelectric diaphragm fabrication system which selectively inserts standardized fixture or accessories such as those described above into diaphragm apertures of piezoelectric diaphragms.

### DETAILED DESCRIPTION OF THE DRAWINGS

In the following description, for purposes of explanation and not limitation, specific details are set forth such as particular architectures, interfaces, techniques, etc. in order to provide a thorough understanding of the present invention. However, it will be apparent to those skilled in the art that the present invention may be practiced in other embodiments that depart from these specific details. In other instances, detailed descriptions of well-known devices, circuits, and methods are omitted so as not to obscure the description of the present invention with unnecessary detail.

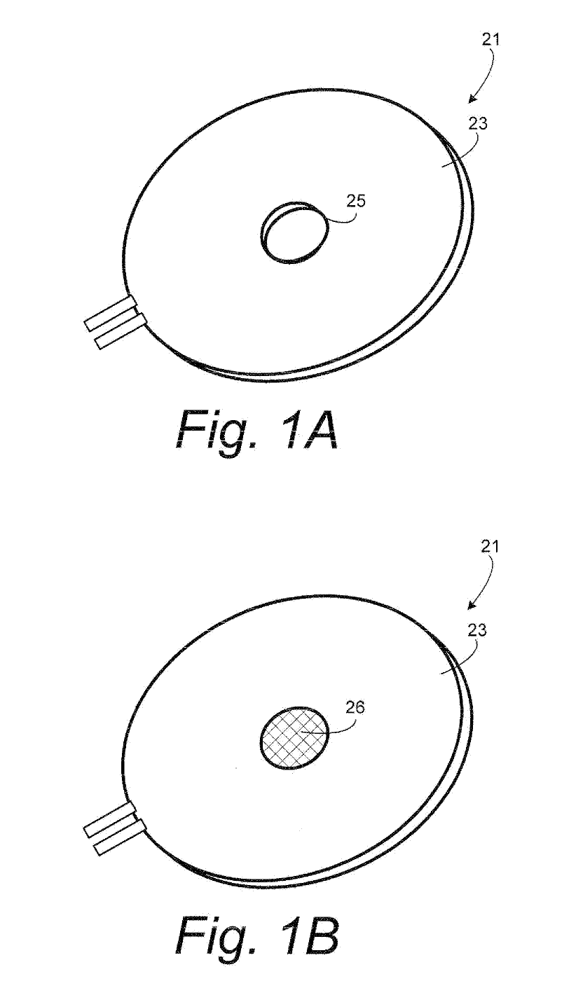

FIG. 1A shows a piezoelectric diaphragm member 21 according to a first example embodiment. The piezoelectric diaphragm member 21 comprises a membrane 23 which includes a piezoelectric layer. In accordance with one aspect of the technology, membrane 23 has a diaphragm aperture 25. In accordance with some aspects of this technology, the diaphragm aperture 25 extends completely through diaphragm member 21 and is selectively coverable by a flap structure, such as a valve flap. In accordance with other aspects of the technology, the diaphragm aperture 25 extends either completely or partially through diaphragm member 21, and can be configured to accommodate a fixture or accessory. FIG. 1B illustrates, by a cross hatched circle, a generic fixture or accessory 26 which is insertable in and/or retainable by diaphragm aperture 25. Various non-limiting and non-exhaustive examples of fixtures or accessories are hereinafter described.

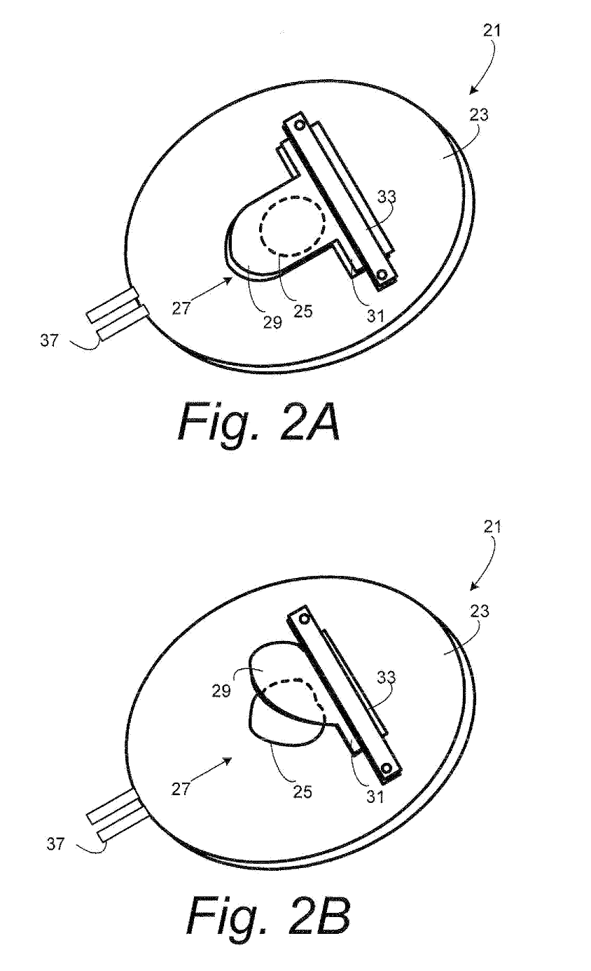

FIG. 2A and FIG. 2B show a piezoelectric diaphragm member 21 according to an example embodiment wherein valve flap 27 is provided on the membrane 23 for selectively opening and closing the diaphragm aperture 25. The diaphragm aperture 25 of the embodiment of FIG. 2A and FIG. 2B extends completely through diaphragm member 21. As hereinafter explained, the valve flap 27 is chosen to be of such mass and size so that it operates in response to movement of the piezoelectric diaphragm member 21 and in response to the fluid being pumped or otherwise processed by piezoelectric diaphragm member 21.

In the example embodiment of FIG. 2A and FIG. 2B, the piezoelectric diaphragm member 21 has an essentially circular shape, with the diaphragm aperture 25 being centrally positioned on the piezoelectric diaphragm member 21. The valve flap 27 is likewise centrally positioned over the diaphragm aperture 25.

In the example configuration, valve flap 27 is mounted in cantilever fashion. The valve flap 27 has a circular, oval, or otherwise suitably formed flap distal portion 29 sized and positioned to cover the diaphragm aperture 25. A flap proximal portion 31 is offset from diaphragm aperture 25 and is the portion of valve flap 27 which is secured to membrane 23. In the illustrated embodiment, a retaining member 35 clamps or otherwise retains flap proximal portion 31 in position on membrane 23. The retaining member 35 can be spot welded, fastened, adhered, or otherwise secured to membrane 23. In other embodiments, retaining member 35 may not be necessary if an underside of flap proximal portion 31 is adhered or otherwise fastened to membrane 23.

In an example, non-limiting implementation, the membrane 23 can be a laminate comprising a piezoelectric core layer; a substrate; and (optionally) a cover layer. In an example implementation, at least one of the substrate and the cover layer comprises stainless steel. For example, the substrate may be stainless steel, and the cover layer aluminum. Alternatively, particularly for handling corrosive fluids, both the substrate and the cover layer may be stainless steel. Examples of pumps with laminate piezoelectric diaphragms are shown in PCT Patent Application PCT/US01/28947, filed 14 Sep. 2001; U.S. patent application Ser. No. 10/380,547, filed Mar. 17, 2003, entitled “Piezoelectric Actuator and Pump Using Same”; U.S. patent application Ser. No. 10/380,589, filed Mar. 17, 2003, entitled “Piezoelectric Actuator and Pump Using Same”, and U.S. Provisional Patent Application 60/670,657 filed Apr. 13, 2005, entitled “PIEZOELECTRIC DIAPHRAGM ASSEMBLIES AND METHODS OF MAKING SAME”, all of which are incorporated herein by reference.

Whether formed as a composite laminate or otherwise, aperture 25 may be formed in piezoelectric diaphragm member 21 in various ways. For example, the aperture 25 may be formed by drilling or etching one or more layers of the piezoelectric diaphragm member 21. When the piezoelectric diaphragm member 21 is formed as a composite, the aperture may be separately formed in one or more layers and then aligned into the composite stack. Alternatively, the aperture may be formed in a single operation through one or more layers of piezoelectric diaphragm member 21. Moreover, it will be recalled that, for some embodiments, aperture 25 extends entirely through piezoelectric diaphragm member 21, while in other embodiments aperture 25 extends only partially into piezoelectric diaphragm member 21.

The piezoelectric diaphragm member 21 has a pair of electrodes 37 extending therefrom. In the laminate implementation of piezoelectric diaphragm member 21, the electrodes can be bonded to the opposite metal layers (e.g., stainless steel, aluminum layers) for contact with electrodes of the piezoelectric core. Formation and positioning of the electrodes 37 can occur in various manners. The electrodes 37 can also be realized by conductive leads formed on adhesive carrier layers, as described in U.S. patent application Ser. No. ______ (attorney docket 4209-103), filed on even date herewith, entitled “PIEZOELECTRIC DIAPHRAGM ASSEMBLY WITH CONDUCTORS ON FLEXIBLE FILM”, which is incorporated herein by reference.

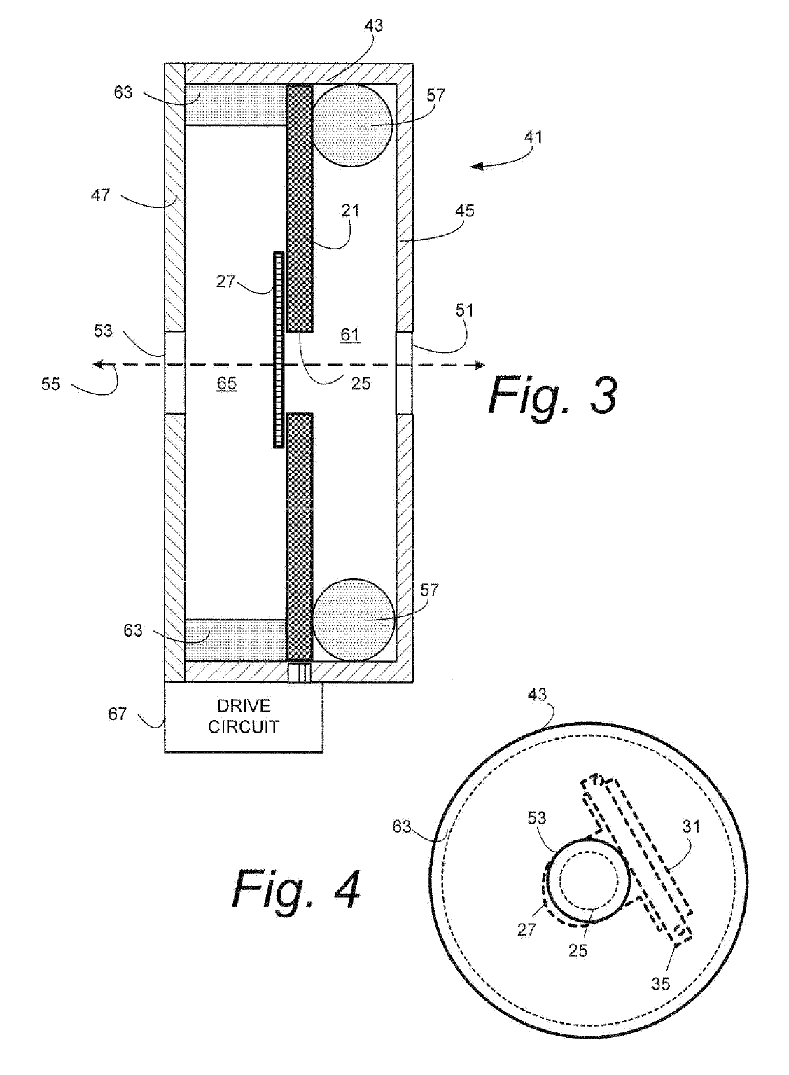

The piezoelectric diaphragm member 21 has particularly advantageous use in a fluidic pump. A non-limiting example of such a pump is shown as pump 41 in FIG. 3 and FIG. 4. Pump 41 has a pump body 43 which, in the illustrated example, happens to be essentially cylindrical in shape (see FIG. 4). The pump body 43 can be formed in various ways, such as (for example) by a pump body receptacle member 45 which receives the piezoelectric diaphragm member 21 and a pump body lid 47 which fits over the pump body receptacle member 45.

Pump body 43 has an inlet port 51 and an opposed outlet port 53. With the particular configuration of pump body 43 shown in FIG. 3, the inlet port 51 is formed or provided in pump body receptacle member 45 while the outlet port 53 is formed or provided in pump body lid 47. Preferably the inlet port 51 and outlet port 53 are aligned along an axial direction of pump 41 (the axial direction being depicted by broken line double headed arrow 55).

The piezoelectric diaphragm member 21 is positioned internally in the pump body 43. In the example configuration of FIG. 3, a spacer ring or gasket 57 is situated around the inner circumference of pump body receptacle member 45 so that the edge or periphery of piezoelectric diaphragm member 21 sits on gasket 57. Thusly situated, the piezoelectric diaphragm member 21 defines an intake chamber 61 substantially between the inlet port 51 and a first side (intake side) of the piezoelectric diaphragm 21. The intake chamber 61 has a nominal depth substantially established by the size of gasket 57. The intake chamber 61 can be dimensioned or provided in other ways.

On the side of piezoelectric diaphragm member 21 which is opposite the intake side, a gasket, spacer, or retainer ring 63 retains and traps piezoelectric diaphragm member 21 in position beneath pump body lid 47. In the space afforded by retainer ring 63, the piezoelectric diaphragm member 21 defines an exhaust chamber 65 substantially between outlet port 53 and the second side (exhaust side) of piezoelectric diaphragm 31. Exhaust chamber 65 can also be dimensioned or provided in other ways.

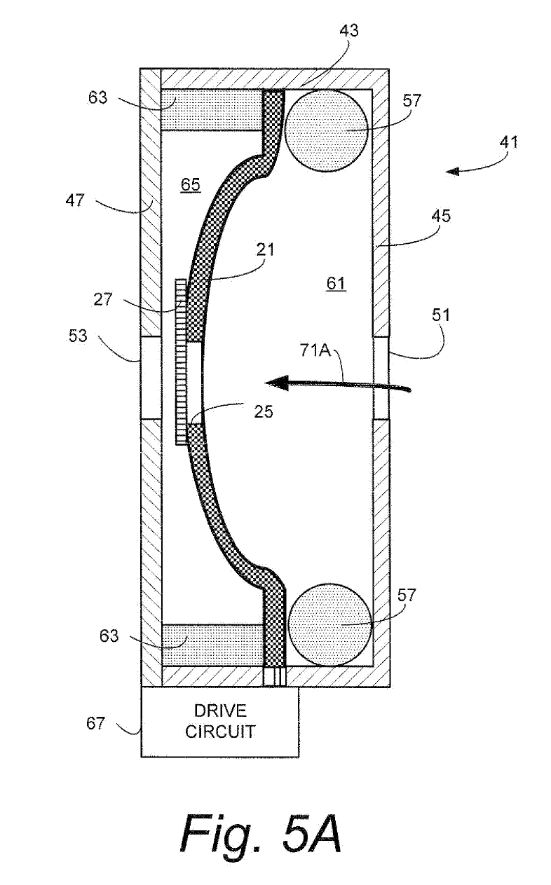

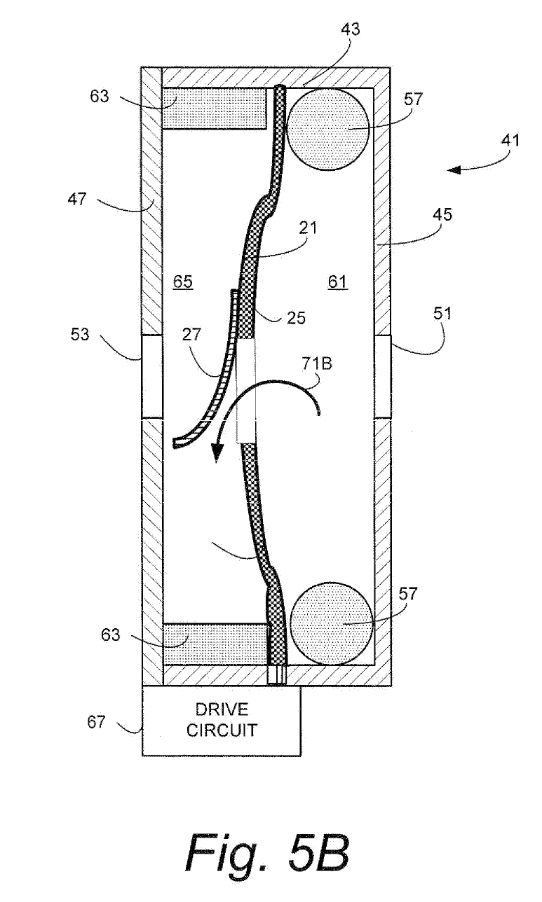

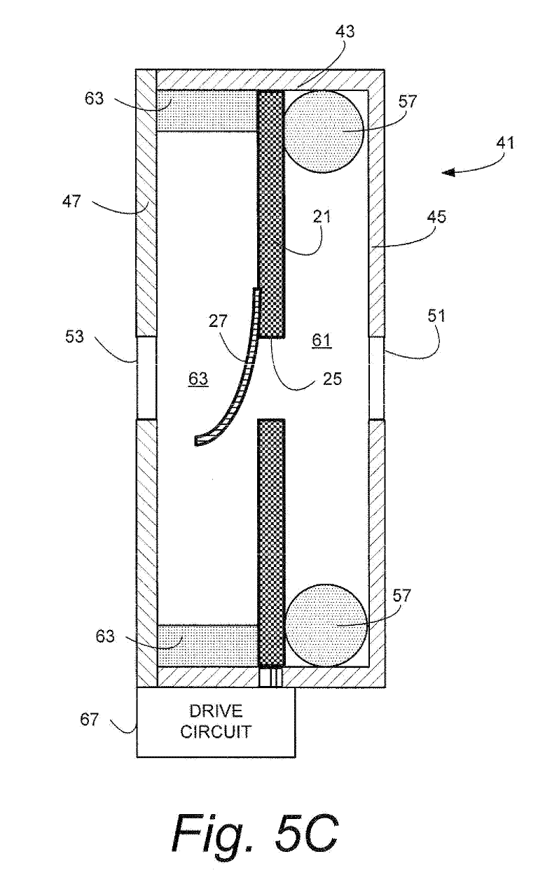

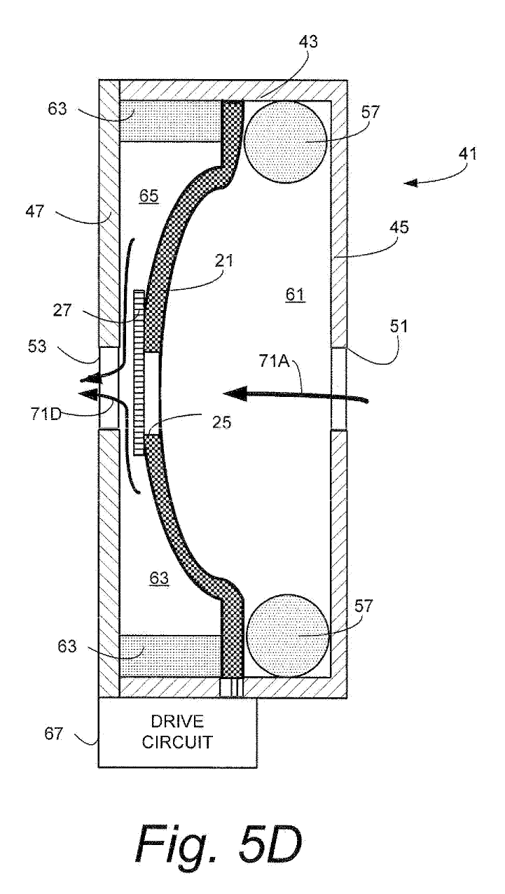

As previously explained, piezoelectric diaphragm member 21 has the diaphragm aperture 25 provided therein. The piezoelectric diaphragm member 21 carries the valve flap 27 for selectively opening and closing the diaphragm aperture 25 in response to movement of the piezoelectric diaphragm 21, as below explained with reference to differing stages of pump operation as illustrated in FIG. 5A through FIG. 5B.

The piezoelectric diaphragm member 21 of pump 41 operates in conjunction with a drive circuit 67 which supplies drive signals to electrodes 37 of piezoelectric diaphragm member 21. Drive circuit 67 may be positioned remotely or proximate pump body 43, an example representative position of mounting of drive circuit 67 being shown.

For sake of the ensuing discussion, it will be assumed that application of zero voltage by the drive circuit 67 to the electrodes 37 of piezoelectric diaphragm member 21 results in piezoelectric diaphragm member 21 maintaining its first position (which could be a rest or minimal curvature (non-deflection) position). At the first position the piezoelectric diaphragm member 21 may be either flat or slightly crowned. Application of a non-zero voltage to piezoelectric diaphragm member 21 causes piezoelectric diaphragm member 21 to dome or displace to a deflected position, e.g. the second position. At the second position the piezoelectric diaphragm member 21 has a significantly greater curvature and thus a bowed appearance in cross section.

FIG. 5A shows pump 41 with the piezoelectric diaphragm member in its second position upon start-up of pump 41. Upon start-up, the valve flap 27 closes, or nearly closes, the diaphragm aperture 25. Upon start-up, no fluid is yet in exhaust chamber 65. Deflection of piezoelectric diaphragm member 21 may assist in priming the pump 41 so that fluid begins to enter intake chamber 61 through inlet port 51, as depicted by arrow 71A.

FIG. 5B shows the piezoelectric diaphragm member 21 in the course of returning from the (priming) second position of FIG. 5A to the first (rest) position. As the piezoelectric diaphragm member 21 travels back toward the first (rest) position, the valve flap 27 lags behind the remainder of membrane 23, particularly with the force of fluid in intake chamber 61 now acting upon the cantilevered valve flap 27. The valve flap 27 thus is at least partially open, permitted fluid to flow from inlet chamber 61 into exhaust chamber 65 as depicted by arrow 71B in FIG. 5B.

FIG. 5C shows the piezoelectric diaphragm member 21 of pump 41 subsequently essentially fully in the first (rest) position. Depending on the pressure of fluid in intake chamber 61, the valve flap 27 may be either partially or almost closed. Thus, at this point in time, fluid is both in the inlet chamber 61 and (by virtue of the previous fluid communication depicted by arrow 7 1B in FIG. 5B) in the exhaust chamber 65. The valve flap 27 only opens when the diaphragm moves from the second position to the first (rest) position or if the inertia of the moving fluid is enough to open the valve flap 27 or if the fluid pressure on the inlet side verses the outlet side is enough to open the valve flap 27.

FIG. 5D shows the piezoelectric diaphragm member 21 being subsequently driven again to the second position, which is more deflected than the first position. In being driven to the second position, the motion and force of membrane 23, as well as the force of fluid now in the exhaust chamber 65, results in valve flap 27 hugging the membrane 23 during its deflection, so that valve flap 27 keeps diaphragm aperture 25 closed. In view of the closure of diaphragm aperture 25 with valve flap 27, the now essentially solid pressure front established by piezoelectric diaphragm member 21 causes at least some of the fluid in exhaust chamber 65 to be expelled through outlet port 53, as depicted by arrow 71D.

Thus, by selectively opening and closing the diaphragm aperture 25, the flap valve 27 selectively allows fluid communication between the intake chamber 61 and the exhaust chamber 65. The valve flap 27 comprises a flexible material which responds to movement of the piezoelectric diaphragm member 21. In this regard, the valve flap 27 at least partially uncovers the diaphragm aperture 25 when the piezoelectric diaphragm member travels to a first position (e.g., FIG. 5B), thereby permitting fluid communication between the intake chamber 61 and the exhaust chamber 65. The first position can be, e.g., a position either of essentially no deflection, small deflection, or minimum deflection. The valve flap 27 covers the diaphragm aperture 25 when the piezoelectric diaphragm 21 member travels to a second position so that the piezoelectric diaphragm member 21 drives fluid from the exhaust chamber 65 (FIG. 5D). The second position is a position of larger deflection than the first position, or even maximum deflection of the piezoelectric diaphragm member 21.

As mentioned above, the material valve flap 27 is chosen to be of such mass and size so that it operates in response to movement of the piezoelectric diaphragm member 21 and the fluid being pumped or otherwise processed by piezoelectric diaphragm member 21. Examples of such materials include films such as polymer films, and light metal such as thin stainless steel.

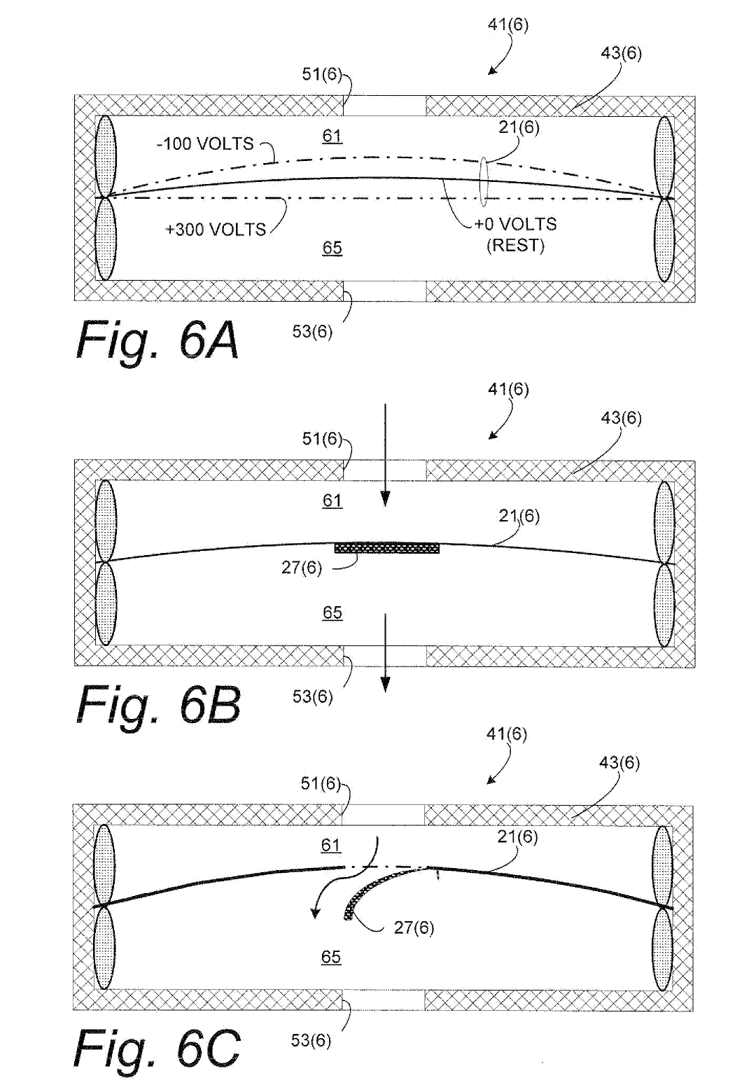

In another embodiment, the piezoelectric diaphragm member is of a type that has a slight dome or crown when at rest (i.e., when zero volts is applied), but which deflects to a greater extent (e.g., greater curvature) when a signal of a first polarity and first magnitude is applied and which becomes essentially flat when a signal of a second polarity and second magnitude is applied thereto. For example, FIG. 6A-FIG. 6C show a pump 41(6) having a piezoelectric diaphragm member 21(6) positioned within pump housing 43(6) in similar manner as previously described embodiments. The pump housing 43(6) has an inlet port 51(6) and an outlet port 53(6), with an intake chamber 61(6) formed between inlet port 51(6) and diaphragm 21(6) and an exhaust chamber 63(6) formed between outlet port 53(6) and diaphragm 21(6). For sake of simplicity the diaphragm aperture and valve of the piezoelectric diaphragm member 21 are not shown in FIG. 6A, although the diaphragm aperture and valve are indeed present.

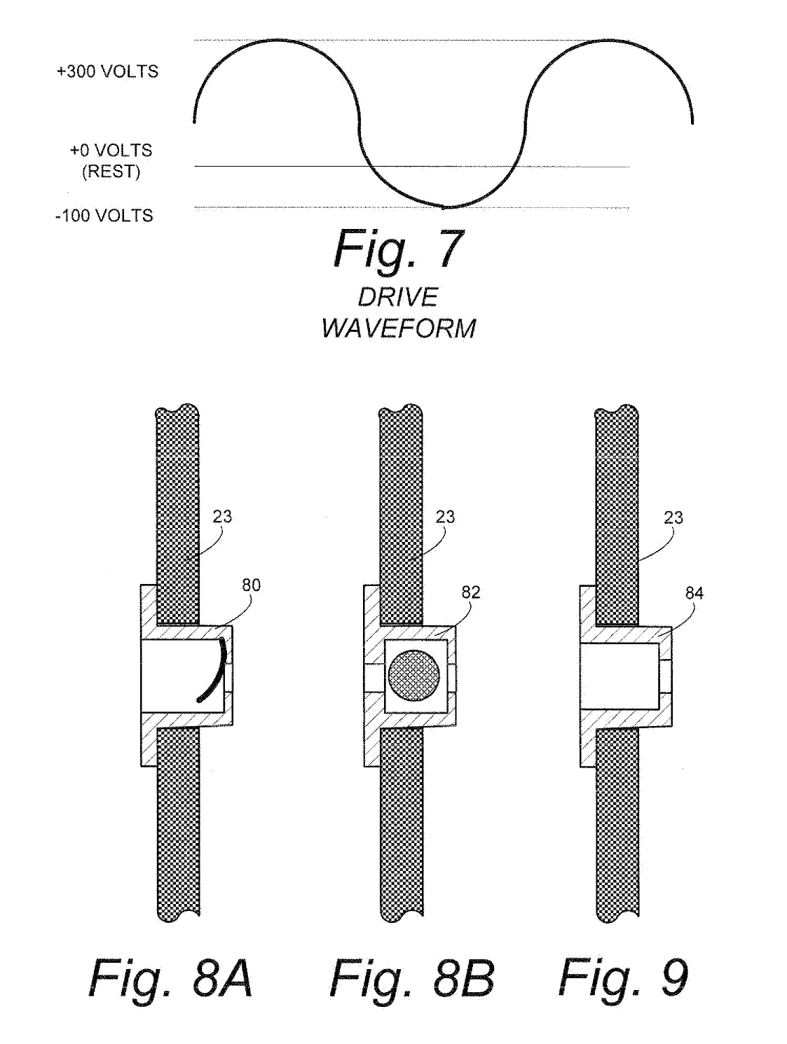

FIG. 6A shows (by its dashed-single dotted line position) that the piezoelectric diaphragm member 21(6) deflects to a greater extent (e.g., greater curvature) when a negative drive signal of approximately 100 volts is applied; has a slight dome or crown when at rest, e.g., when zero volts is applied (as shown by its solid line position); and becomes essentially flat (as shown by its dashed-double dotted line position) when a signal of a second polarity and second magnitude is applied thereto, e.g., when a positive drive signal of approximately 300 volts is applied. FIG. 7 illustrates the driving waveform that results in the positions of diaphragm aperture 25 which are illustrated in FIG. 6A.

FIG. 6B shows that a flap valve 27(6) which serves as the closure member for the piezoelectric diaphragm member 21(6) essentially closes the diaphragm aperture when the piezoelectric diaphragm member is at rest (zero volts). FIG. 6C shows the flap valve 27(6) opening to admit fluid from the inlet side 61(6) of the pump to the outlet or exhaust side 65(6) of the pump when the piezoelectric diaphragm member 21(6) is actuated by the negative phase of the drive signal.

In the FIG. 6A-FIG. 6C embodiment and all other embodiments, the ports do not have to be in-line, but can be offset or in any desired configuration. Nor do the inlet and outlet ports of the pump necessarily have to be oriented perpendicularly to the plane of the piezoelectric diaphragm member. For example, the ports can be arranged parallel to the plane of the piezoelectric diaphragm member as understood by various documents incorporated herein.

The preceding embodiments illustrate closure members which are accommodated into the diaphragm aperture of the piezoelectric diaphragm member. When such embodiments are incorporated into pumps, both sides of the piezoelectric diaphragm member are exposed to the fluid (e.g. air or gas). Advantageously the diaphragm is exposed only to the differential pressure of the system drop. By contrast, for pumps in which the fluid is confined to a pumping chamber on one side of the diaphragm, the diaphragm experiences the differential pressure of the system pressure on the fluidic side of the diaphragm, but on the non-fluidic side of the diaphragm the diaphragm typically experiences atmospheric pressure. The embodiments described herein having the diaphragm aperture are advantageous for many types of systems including, e.g., pressurized systems such as refrigerated or pressurized cooling loops or systems where higher system differential pressures are required that exceed the standard diaphragm pump capability.

In other embodiments, the aperture in the piezoelectric diaphragm accommodates a diaphragm accessory or fixture. The diaphragm accessory or fixture is preferably inserted through the plural layers of the multi-layer composite piezoelectric diaphragm member, and as such has an accessory or fixture body suitably sized for snug insertion or adhesion into the diaphragm aperture. Within its periphery the accessory or fixture body can include a feature such as a valve or a projection or a sensor.

Examples of diaphragm accessories or fixtures include valves, such as the flapper valve accessory 80 of FIG. 8A and the ball valve accessory 82 of FIG. 8B. Other types of valve accessories are also possible. Another example of a diaphragm accessory is a precision orifice accessory 84 such as that shown in FIG. 9. The diameter of the orifice of orifice accessory 84 can be strictly controlled. Orifice assemblies having orifices of differing sizes can be fabricated.

An example of a projection accessory is a stud or standoff, which may have a threaded shank or the like such as the threaded stud accessory 86 of FIG. 10. The projection type accessory may engage or actuate further apparatus. Such engagement can be a threaded engagement, or abutment/contact, for example.

Another example of an accessory or fixture is a sensor accessory, such as sensor accessory 88 illustrated in FIG. 11. The sensor accessory can include a pressure type sensor (such as a transducer, for example), a chemical sensor, or any other type of sensor suitable for checking or sensing conditions, e.g., conditions in a pump chamber, for example.

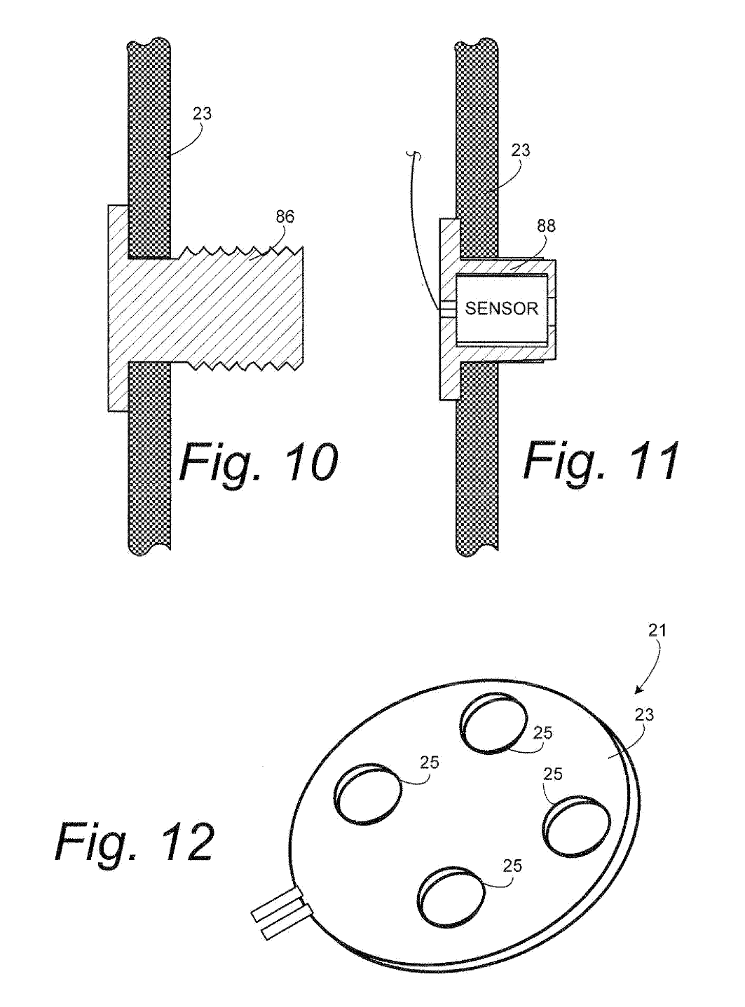

Whatever type of accessory or fixture is employed in the diaphragm aperture, it will be appreciated that the diaphragm aperture, and thus the accessory or fixture will be placed and oriented (e.g., facing fluid or not facing fluid, or facing inlet or outlet) according to the task to be performed by the accessory or fixture. Thus, the diaphragm aperture, diaphragm accessory or fixture, or closure member may be centrally positioned on the piezoelectric diaphragm member, or in any other suitable non-central position. One or more diaphragm apertures, and hence one or more corresponding diaphragm accessories or fixtures, or closure members, may also be provided and arranged as desired. In this regard, whereas FIG. 1A showed a piezoelectric diaphragm element having a single (e.g., central) diaphragm aperture, the piezoelectric diaphragm element of FIG. 12 has plural diaphragm apertures. Each aperture can accommodate a fixture or accessory.

The diameter of the appropriate accessory or fixture is thus chosen to provide a snug, typically fluid-tight fit in to the diaphragm aperture 25. The accessory or fixture is retained within the diaphragm aperture 25 by any suitable means, such as (for example) an adhesive or epoxy. The accessory or fixture may have a cap or enlarged diameter end which contacts a major surface of the diaphragm, thereby providing an interface (between the diaphragm surface and the cap) for application of the adhesive/epoxy. Rather than securing the fixture or accessory using an adhesive/epoxy, the fixture or accessory can be retained in diaphragm aperture 25 by snap-fit or threaded engagement, for example. Moreover, it will be recalled that, in some embodiments, the aperture 25 need not extend through the entire thickness of piezoelectric diaphragm member 21. In such embodiments, the fixture or accessory has a shank or anchor portion suitable to the depth of the aperture 25, and engages the aperture 25 in any suitable manner such as those aforementioned (e.g., epoxy, adhesive, threaded, snap-fit, for example).

A batch or lot of aperture-bearing piezoelectric diaphragm members can be produced with a specified or even standardized aperture, so that some of the diaphragm members of the lot can be fitted with diaphragm accessories or fixtures of a first type, while other members of the lot can be fitted with diaphragm accessories or fixtures of a second type, and so forth. By making the apertures of the piezoelectric diaphragm members of prearranged size and configuration, and by also making various types of diaphragm accessories or fixtures or closure members of suitable size and configuration for mating/insertion into the apertures, manufacturing capability is enhanced with interchangeable and easily configurable parts.

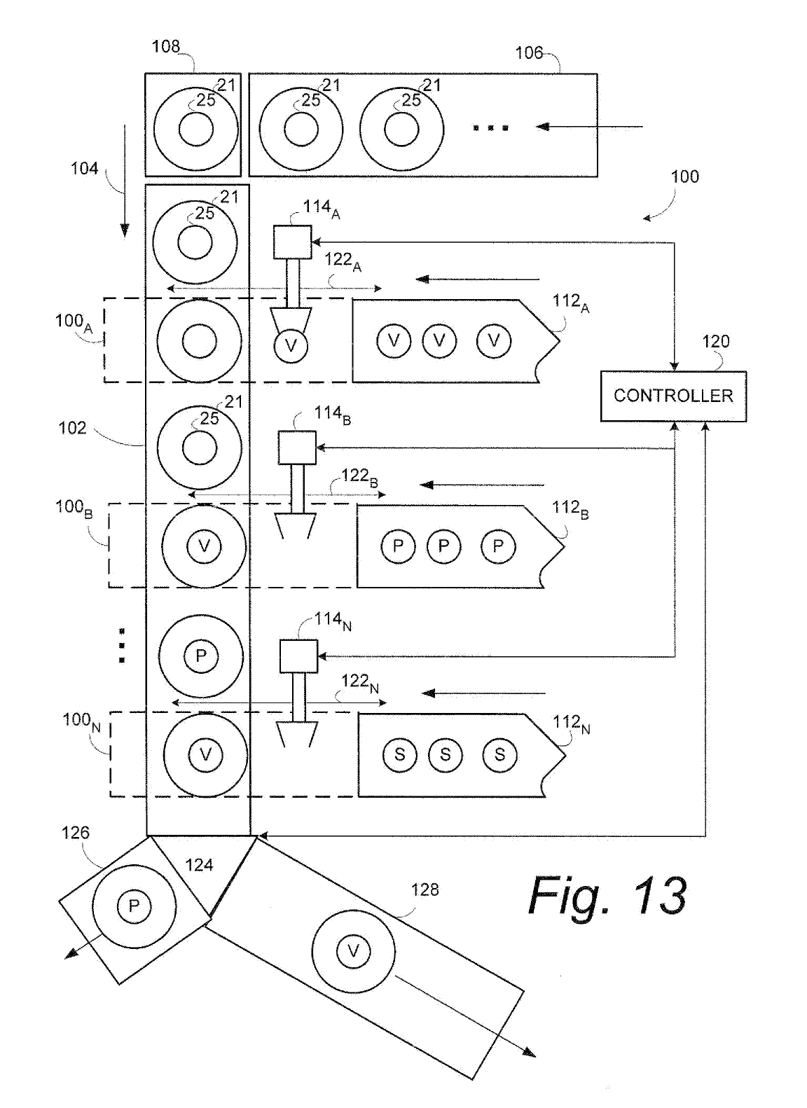

FIG. 13 is a diagrammatic view of an automated piezoelectric diaphragm fabrication system 100 which selectively inserts standardized fixture or accessories such as those described above into diaphragm apertures of piezoelectric diaphragms. The automated piezoelectric diaphragm fabrication system 100 includes a main or production conveyor line 102 which travels in a direction depicted by main conveyor direction arrow 104. The production conveyor line 102 receives a stream of piezoelectric diaphragm member 23 with their pre-formed diaphragm apertures 25. In particular, the piezoelectric diaphragm member 23 is supplied by a diaphragm supply conveyor 106 other suitable feeding means. In the case that the diaphragm supply conveyor 106 travels in a direction different from main conveyor direction arrow 104, a direction translator conveyor section 108 can be utilized to impart or introduce the piezoelectric diaphragm member 23 to the production conveyor line 102.

The production conveyor line 102 travels past a series of selectively actuatable work stations 110_{A}-110_{N}. Each work station 110 includes means for supplying a fixture, such as a fixture discharge hopper or a fixture supply conveyor 112, and a fixture retrieval/insertion actuator 114.

In the particular implementation shown in FIG. 13, work station 110_{A} is activated and utilized when the diaphragm aperture 25 of a piezoelectric diaphragms member 23 passing thereby on production conveyor line 102 is to have a valve fixture inserted therein. Accordingly, the fixtures depicted as circles on fixture supply conveyor 112_{A} circumscribe the letter “V”, representing a valve fixture. Work station 110_{B} is activated and utilized when the diaphragm aperture 25 of a piezoelectric diaphragms member 23 passing thereby on production conveyor line 102 is to have a projection fixture inserted therein, i.e., a stud/standoff or threaded shaft, for example. Accordingly, the fixtures depicted as circles on fixture supply conveyor 112_{B} circumscribe the letter “P”, representing a projection fixture. Similarly, work station 110_{N} is activated and utilized when the diaphragm aperture 25 is to have a sensor fixture inserted therein. Accordingly, the fixtures depicted as circles on fixture supply conveyor 112_{N} circumscribe the letter “S”, representing a sensor fixture. Although three such example work stations are illustrated in FIG. 13, it will be appreciate that fewer than or more than three work stations may in fact be provided. Each work station 110 can be stocked for feeding a unique type of fixture. Alternatively, plural work stations can be stocked for feeding the same type of fixture.

Operation of automated piezoelectric diaphragm fabrication system 100 is governed by a controller 120. The controller 120 supervises and controls the transport speed and operation of production conveyor line 102 generally (such as, e.g., detecting conveyance conditions or faults via various sensors), but also actuation of the respective plural work stations 110. The controller 120 is connected to each fixture retrieval/insertion actuator 114 for prompting the respective fixture retrieval/insertion actuator 114 when to take action. The action performed by each fixture retrieval/insertion actuator 114, when so authorized, is to fetch a fixture from its respective fixture supply conveyor 112 and insert the fetched fixture into the diaphragm aperture 25 of the piezoelectric diaphragm member 21 which will rendezvous at the respective work station 110. Such fetching and insertion are reflected by arrow 122 for each work station 110.

In the particular scenario shown in FIG. 13, controller 120 has been programmed to insert a valve fixture “V” from work station 110_{A} into every odd numbered piezoelectric diaphragm member 21 and to insert a projection fixture “P” from work station 110_{B} into every even numbered piezoelectric diaphragm member 21. Moreover, the automated piezoelectric diaphragm fabrication system 100 includes a discharge section 124 also controlled by controller 120. The discharge section 124 serves, e.g., to divert a piezoelectric diaphragm member 21 which has already been processed and fitted with a fixture into an appropriate discharge conveyor route. In the illustration shown in FIG. 13, piezoelectric diaphragm member 21 having a valve fixture are routed onto discharge conveyor 128 while piezoelectric diaphragm member 21 having a projection fixture are routed onto discharge conveyor 126. Other discharge systems, whether more simple or complex, are within the purview of the technology.

In automated piezoelectric diaphragm fabrication system 100 the fixtures or accessories may be inserted into the diaphragm apertures 25 of their respective piezoelectric diaphragm member 21 either by pressure fitting, or by adhesive, or any sealing means. Such can be accommodated by an additional work station whereat a sealant or adhesive is applied to each diaphragm aperture 25, or as an adjunct at each work station 110.

FIG. 13 thus illustrates a method of making piezoelectric diaphragm members. The method includes providing plural piezoelectric diaphragm members, each of the piezoelectric diaphragm members having an aperture extending in a thickness direction of the piezoelectric diaphragm member, the aperture of each of the plural piezoelectric diaphragm members having an essentially same aperture size. The method further includes selecting a selected type of diaphragm fixture from plural diaphragm fixture types, the diaphragm fixtures of each of the plural diaphragm fixture types having essentially a same fixture size suitable for insertion into the aperture of each of the plural piezoelectric diaphragm members. The method also includes inserting diaphragm fixtures of the selected type into at least some of the plural piezoelectric diaphragm members. Such insertion can include adhering, or otherwise securing, the diaphragm fixtures of the selected type into at least some of the plural piezoelectric diaphragm members. At least one of the plural diaphragm fixture types can comprise a valve fixture, a projection fixture, or a sensor feature. Other types of fixtures or accessories are also possible.

Thus, FIG. 13 describes an automated manner of making piezoelectric diaphragm members, under supervision or governance of a programmed controller or processor. The functions of such “processor” or “controller” may be provided through the use of dedicated hardware as well as hardware capable of executing software in association with appropriate software. When provided by a processor, the functions may be provided by a single dedicated processor, by a single shared processor, or by a plurality of individual processors, some of which may be shared or distributed. Moreover, explicit use of the term “processor” or “controller” should not be construed to refer exclusively to hardware capable of executing software, and may include, without limitation, digital signal processor (DSP) hardware, read only memory (ROM) for storing software, random access memory (RAM), and non-volatile storage.

It will be appreciate that the standardized or consistent size of the diaphragm aperture and the fixture or accessory size facilitate the method discussed above also being practiced manually or semi-automatically.

Although various embodiments have been shown and described in detail, the claims are not limited to any particular embodiment or example. None of the above description should be read as implying that any particular element, step, range, or function is essential such that it must be included. It is to be understood that the invention is not to be limited to the disclosed embodiment, but on the contrary, is intended to cover various modifications and equivalent arrangements.

What is claimed is:

1. A piezoelectric diaphragm member comprising a membrane comprising a piezoelectric layer, the membrane having a diaphragm aperture provided therein.

2. The apparatus of claim 1, further comprising a valve flap connected to the for piezoelectric diaphragm member for selectively opening and closing the diaphragm aperture in response to movement of the piezoelectric diaphragm.

3. The apparatus of claim 1, wherein the membrane is a laminate comprising a piezoelectric core layer; a substrate; and optionally a cover layer.

4. The apparatus of claim 2, wherein at least one of the substrate and the cover layer comprises stainless steel.

5. The apparatus of claim 1, further comprising a diaphragm accessory or fixture inserted into the diaphragm aperture.

6. The apparatus of claim 5, wherein the diaphragm accessory or fixture comprises a flapper valve.

7. The apparatus of claim 5, wherein the diaphragm accessory or fixture comprises a ball valve.

8. The apparatus of claim 5, wherein the diaphragm accessory or fixture comprises a precision orifice.

9. The apparatus of claim 5, wherein the diaphragm accessory or fixture comprises a threaded stud for engaging further apparatus.

10. The apparatus of claim 5, wherein the diaphragm accessory or fixture comprises a projection.

11. The apparatus of claim 5, wherein the diaphragm accessory or fixture comprises a sensor.

12. A method of making diaphragms comprising
providing plural piezoelectric diaphragm members, each of the piezoelectric diaphragm members having an aperture extending in a thickness direction of the piezoelectric diaphragm member, the aperture of each of the plural piezoelectric diaphragm members having an essentially same aperture size;
selecting a selected type of diaphragm fixture from plural diaphragm fixture types, the diaphragm fixtures of each of the plural diaphragm fixture types having essentially a same fixture size suitable for insertion into the aperture of each of the plural piezoelectric diaphragm members;
inserting diaphragm fixtures of the selected type into at least some of the plural piezoelectric diaphragm members.

13. The method of claim 12, wherein at least one of the plural diaphragm fixture types comprises a valve fixture, a projection fixture, or a sensor feature.

14. The method of claim 12, further comprising adhering the diaphragm fixtures of the selected type into at least some of the plural piezoelectric diaphragm members.

15. A pump comprising:
a pump body having an inlet port and an opposed outlet port;
a piezoelectric diaphragm member positioned internally in the pump body for at least partially defining an intake chamber substantially between the inlet port and the piezoelectric diaphragm and for at least partially defining an exhaust chamber substantially between the outlet port and the piezoelectric diaphragm, the piezoelectric diaphragm member having a diaphragm aperture provided therein;
wherein the piezoelectric diaphragm member carries a valve flap for selectively opening and closing the diaphragm aperture in response to movement of the piezoelectric diaphragm and thereby selectively allowing fluid communication between the intake chamber and the exhaust chamber.

16. The pump of claim 15, wherein the piezoelectric diaphragm member has an essentially circular shape, and wherein the diaphragm aperture is centrally positioned on the piezoelectric diaphragm member.

17. The pump of claim 15, wherein the valve flap comprises a flexible material which responds to movement of the piezoelectric diaphragm member whereby the valve flap at least partially uncovers the diaphragm aperture when the piezoelectric diaphragm member travels to a first position for permitting the fluid communication between the intake chamber and the exhaust chamber, and whereby the valve flap covers the diaphragm aperture when the piezoelectric diaphragm member travels to a second position so that the piezoelectric diaphragm member drives fluid from the exhaust chamber.
